(19) United States
(12) Patent Application Publication
(10) Pub. No.: US 2026/0206489 A1
(43) Pub. Date: Jul. 16, 2026

(54) THERMOELECTRIC MODULE ARRAY AND POWER GENERATION SYSTEM INCLUDING SAME

(71) Applicant: LG INNOTEK CO., LTD., Seoul (KR)

(72) Inventors: Young Sam YOO, Seoul (KR); Jong Hyun KIM, Seoul (KR); Yong Sang CHO, Seoul (KR)

(21) Appl. No.: 19/134,344

(22) PCT Filed: Dec. 7, 2023
(86) PCT No.: PCT/KR2023/020112

§ 371 Date: May 30, 2025

(30) Foreign Application Priority Data
Dec. 9, 2022 (KR) 10-2022-0171152

(51) Int. Cl. H10N 10/17

(52) U.S. Cl. CPC H10N 10/17; H10N 10/80; H10N 10/81

(57) ABSTRACT

A thermoelectric module array according to an embodiment of the present invention comprises: a first thermoelectric module; and a second thermoelectric module disposed adjacent to the first thermoelectric module along a first direction, wherein each of the first thermoelectric module and the second thermoelectric module includes a heat sink and a connector, the heat sink includes a groove formed to extend in the first direction so as to allow a first fluid to flow in the first direction, and a first connector of the first thermoelectric module and a second connector of the second thermoelectric module are disposed along the first direction.

### TECHNICAL FIELD

The present invention relates to a thermoelectric module array, and a power generation system including the same.

### BACKGROUND ART

A thermoelectric effect is a phenomenon that occurs due to movement of electrons and holes within a material, involving direct energy conversion between heat and electricity.

Thermoelectric element is a general term for elements that utilize the thermoelectric phenomenon, and a thermoelectric element has a structure in which a PN junction pair is formed by bonding a P-type thermoelectric material and an N-type thermoelectric material between metal electrodes.

Thermoelectric elements may be classified into elements that utilize temperature changes in electrical resistance, elements that utilize the Seebeck effect which is a phenomenon in which an electromotive force is generated by a temperature difference, and elements that utilize the Peltier effect which is a phenomenon in which heat absorption or heat generation occurs due to an electric current.

Thermoelectric elements are widely used in home appliances, electronic components, and communication components. For example, thermoelectric elements may be used in cooling devices, heating devices, and power generation devices. Thus, the demand for thermoelectric performance of thermoelectric elements is increasing.

Recently, there has been a need to generate electricity using thermoelectric elements and high temperature waste heat generated from an engine of an automobile, a ship, and the like. In this case, a fluid flow portion is disposed on the low temperature part side of the thermoelectric element, a heat sink is disposed on the high temperature part side of the thermoelectric element, and a fluid having a higher temperature than a fluid passing through the fluid flow portion may pass through the heat sink. Accordingly, electricity can be generated by a temperature difference between the low temperature part and the high temperature part of the thermoelectric element, and power generation performance may vary according to a structure of a power generation device.

### DETAILED DESCRIPTION OF INVENTION

### Technical Problem

The present invention is directed to providing a structure of an efficient thermoelectric module array, and a structure of a thermoelectric module array or thermoelectric system that takes into account a differential pressure in a power generation system.

### Technical Solution

A thermoelectric module array according to an embodiment of the present invention includes a first thermoelectric module, and a second thermoelectric module disposed adjacent to the first thermoelectric module in a first direction, wherein each of the first thermoelectric module and the second thermoelectric module includes a heat sink and a connector, the heat sink includes a groove formed to extend in the first direction so that a first fluid flows in the first direction, and a first connector of the first thermoelectric module and a second connector of the second thermoelectric module are disposed in the first direction.

The first connector of the first thermoelectric module and the second connector of the second thermoelectric module may be connected by a wire that extends in the first direction.

The heat sink and the connector may be disposed to overlap each other in a second direction perpendicular to the first direction.

The thermoelectric module array may further include a shield member configured to cover the first connector and the second connector together and disposed to extend in the first direction.

Each of a first heat sink of the first thermoelectric module and a second heat sink of the second thermoelectric module may include a plurality of sub-heat sinks, and a distance between the first heat sink of the first thermoelectric module and the second heat sink of the second thermoelectric module may be greater than or equal to a distance between the plurality of sub-heat sinks within the first heat sink.

The distance between the first heat sink of the first thermoelectric module and the second heat sink of the second thermoelectric module may be one time or more and two times or less the distance between the plurality of sub-heat sinks within the first heat sink.

Each of the first thermoelectric module and the second thermoelectric module may include a first substrate on which the connector is disposed and a second substrate on which the heat sink is disposed, and a plurality of P-type legs and a plurality of N-type legs may be disposed between the first substrate and the second substrate.

The thermoelectric module array may further include a first electrode disposed between the plurality of P-type legs and the plurality of N-type legs and the first substrate, the first electrode may include an extension portion which extends in a second direction perpendicular to the first direction, and the connector may be disposed on the extension portion.

The first substrate may include a region in which the heat sink is disposed and an extension region which extends in the second direction from the region in which the heat sink is disposed, the heat sink may includes an uneven shape, and a distance of the extension region extended in the second direction may be greater than a distance between protrusions having the uneven shape.

The distance of the extension region extended in the second direction may be 1.5 times or more and 7.5 times or less the distance between the protrusions.

The first thermoelectric module and the second thermoelectric module may be disposed on the same plane.

A distance in the first direction between the first heat sink of the first thermoelectric module and the second heat sink of the second thermoelectric module may be smaller than a distance between the first heat sink of the first thermoelectric module and an edge of the first substrate of the first thermoelectric module in the second direction perpendicular to the first direction.

The distance between the first heat sink of the first thermoelectric module and the edge of the first substrate in the second direction may be 1.1 times or more and 2.5 times or less the distance in the first direction between the first heat sink of the first thermoelectric module and the second heat sink of the second thermoelectric module.

The first thermoelectric module and the second thermoelectric module may include a fluid flow portion disposed on a surface opposite to a surface on which the heat sink is disposed and having a passage through which a second fluid flows.

The passage may be formed in the second direction perpendicular to the first direction.

A power generation system using a flow of a fluid according to another embodiment of the present invention includes a first thermoelectric module including a first connector, and a second thermoelectric module including a second connector electrically connected to the first connector, wherein the first fluid flows in a first direction, and the first connector and the second connector may be sequentially disposed in the first direction.

The first thermoelectric module and the second thermoelectric module each may include a heat sink, and the heat sink may be in direct contact with the first fluid.

The heat sink may include a groove formed in the first direction.

The power generation system may include a second fluid flowing in a direction different from the first direction and having a different temperature from the first fluid.

The first fluid may have a higher temperature than the second fluid, and the first fluid may be a gas and the second fluid may be a liquid.

A thermoelectric module array according to still another embodiment of the present invention includes a first thermoelectric module, and a second thermoelectric module disposed adjacent to the first thermoelectric module in a first direction, wherein each of the first thermoelectric module and the second thermoelectric module includes a heat sink and a connector, the heat sink includes a plurality of protrusions and a recessed portion between the plurality of protrusions, and the connector of the first thermoelectric module and the connector of the second thermoelectric module are disposed parallel to an extension direction of the protrusions.

### Advantageous Effects

According to an embodiment of the present invention, an arrangement structure of a thermoelectric module array can be improved so that the maximum number of thermoelectric modules can be accommodated within a limited space. Accordingly, a power generation capacity that can be obtained within a limited space and a heat capacity range can be maximized.

### DESCRIPTION OF DRAWINGS

FIG. 1 is a perspective view of a thermoelectric device according to an embodiment of the present invention.

FIG. 2 is an exploded perspective view of the thermoelectric device according to the embodiment of the present invention.

FIGS. 3 and 4 illustrate a structure of a thermoelectric element.

FIG. 5 is a perspective view of a thermoelectric module according to an embodiment of the present invention.

FIG. 6 is an exemplary diagram of a first substrate and a first electrode in a thermoelectric module according to the embodiment of FIG. 5.

FIG. 7 is a perspective view of a thermoelectric module according to another embodiment of the present invention.

FIG. 8 is an exemplary diagram of a first substrate and a first electrode in the thermoelectric module according to the embodiment of FIG. 7.

FIG. 9 is a perspective view of a thermoelectric module according to still another embodiment of the present invention.

FIG. 10 is an exemplary diagram of a first substrate and a first electrode in the thermoelectric module according to the embodiment of FIG. 9.

FIG. 11 is a perspective view of a thermoelectric module according to yet another embodiment of the present invention.

FIG. 12 is an exemplary diagram of a first substrate and a first electrode in the thermoelectric module according to the embodiment of FIG. 11.

FIG. 13 is a plan view of a thermoelectric module array according to an embodiment of the present invention.

FIGS. 14 and 15 are plan and perspective views of the thermoelectric module array of FIG. 13 from which a shield member is removed.

FIG. 16 is a layout diagram of a power generation system according to a comparative example.

FIG. 17 is a layout diagram of a power generation system according to an embodiment.

FIG. 18 is a diagram showing a simulation of a differential pressure according to a length of a path through which a fluid passes in the comparative example and the embodiment.

### MODES OF THE INVENTION

Exemplary embodiments of the present invention will be described in detail below with reference to the accompanying drawings.

However, the technical idea of the present invention is not limited to the described embodiments, but can be implemented in various different forms, and within the scope of the technical idea of the present invention, one or more of the components among the embodiments may be selectively combined or substituted and used.

In addition, the terms (including technical and scientific terms) used in the embodiments of the present invention may be interpreted as having meanings that are generally understood by those of ordinary skill in the technical field to which the present invention belongs, unless explicitly and specifically defined and described, and commonly used terms such as terms defined in dictionaries may be interpreted in consideration of their contextual meaning in the related art.

Additionally, the terms used in the embodiments of the present invention are for the purpose of describing the embodiments and are not intended to limit the present invention.

In this specification, the singular may also include the plural unless the context clearly dictates otherwise, and when the description “at least one (or one or more) of A, B, and C,” it may include one or more of all possible combinations of A, B, and C.

Additionally, in describing components of embodiments of the present invention, terms such as “first,” “second,” “A,” “B,” “(a),” “(b),” or the like may be used.

These terms are only intended to distinguish one component from another, and are not intended to limit the nature, order, or sequence of the component.

In addition, when a component is described as being “connected,” “coupled,” or “linked” to another component, it may include not only cases in which the component is directly connected, coupled, or linked to the other component, but also cases in which the component is “connected,” “coupled,” or “linked” by another component between the component and the other component.

Additionally, when a component is described as being formed or disposed “on (above) or below (under)” another component, “above” or “below” includes not only cases in which the two components are in direct contact with each other, but also cases in which one or more other components are formed or disposed between the two components. Additionally, when expressed as “above or below,” it can include the meaning of not only the upward direction but also the downward direction based on one component.

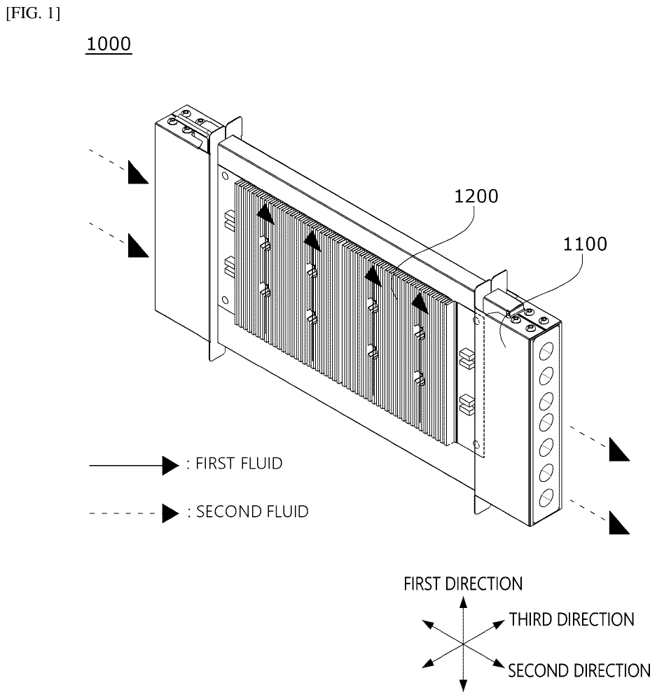

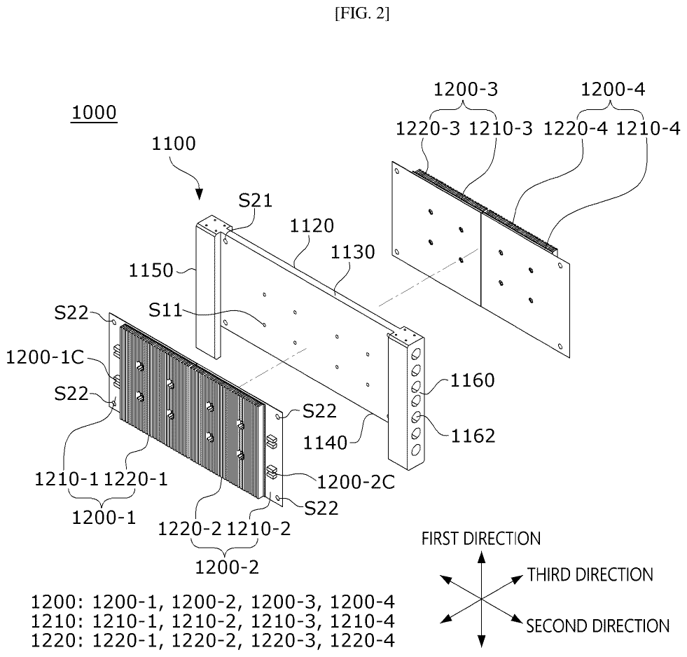

FIG. 1 is a perspective view of a thermoelectric device according to an embodiment of the present invention, and FIG. 2 is an exploded perspective view of the thermoelectric device according to the embodiment of the present invention.

Referring to FIGS. 1 and 2, the thermoelectric device 1000 includes a fluid flow portion 1100 and a thermoelectric module 1200 disposed on a surface of the fluid flow portion 1100. A plurality of thermoelectric devices 1000 may be disposed in at least one of a first direction, a second direction, and a third direction to form a thermoelectric system. In this specification, the thermoelectric device 1000 or thermoelectric system may be used interchangeably with a thermoelectric module array.

The thermoelectric device 1000 according to the embodiment of the present invention may generate power utilizing a temperature difference between a fluid flowing through the inside of the fluid flow portion 1100 and a fluid passing through the outside of the fluid flow portion 1100. Accordingly, the thermoelectric device 1000 may also be referred to as a power generation device or power generation system. In this specification, the fluid passing through the outside of the fluid flow portion is referred to as a first fluid, and the fluid passing through the inside of the fluid flow portion 1100 is referred to as a second fluid, but the opposite thereof may also be used.

The second fluid introduced into the fluid flow portion 1100 may be water, but is not limited thereto, and may be any type of fluid having cooling performance. A temperature of the second fluid introduced into the fluid flow portion 1100 may be less than 100° C., preferably less than 50° C., and more preferably less than 40° C., but is not limited thereto, and the second fluid may be a fluid having a lower temperature than the first fluid. A temperature of the second fluid discharged after passing through the fluid flow portion 1100 may be higher than a temperature of the second fluid introduced into the fluid flow portion 1100.

The second fluid is introduced through a fluid inlet of the fluid flow portion 1100 and is discharged through a fluid outlet. In order to facilitate the introduction and discharge of the second fluid and to support the fluid flow portion 1100, an inlet flange (not illustrated) and an outlet flange (not illustrated) may be further disposed on the fluid inlet side and the fluid outlet side of the fluid flow portion 1100, respectively. Alternatively, a plurality of fluid inlets (not illustrated) may be formed in a first surface 1110 of the fluid flow portion 1100, a second surface 1120 facing the first surface 1110, and a fifth surface 1150 disposed perpendicular to a third surface 1130 between the first surface 1110 and the second surface 1120, and a plurality of fluid outlets 1162 may be formed in a sixth surface 1160 facing the fifth surface 1150. The plurality of fluid inlets (not illustrated) and the plurality of fluid outlets 1162 may be connected to a plurality of fluid passage pipes (not illustrated) within the fluid flow portion 1100. Thus, the second fluid introduced into each of the fluid inlets may pass through each of the fluid passage pipes and then may be discharged through each of the fluid outlets 1162.

However, this is an example, and the number, location, shape, and the like of the fluid inlets and fluid outlets are not limited thereto. The fluid flow portion 1100 may be formed with one fluid inlet, one fluid outlet, and a fluid passage pipe connecting them.

Meanwhile, the first fluid passes through the outside of the fluid flow portion 1100, for example, a heat sink 1220 of the thermoelectric module 1200 disposed outside the fluid flow portion 1100. The first fluid may flow in contact with the heat sink 1220. The first fluid may be waste heat generated from an engine of an automobile, ship, and the like, but is not limited thereto. For example, a temperature of the first fluid may be 100° C. or higher, preferably 200° C. or higher, and more preferably 220° C. to 250° C., but is not limited thereto, and the first fluid may be a fluid having a temperature higher than the temperature of the second fluid.

In this specification, an example in which the temperature of the second fluid flowing through the inside of the fluid flow portion 1100 is lower than the temperature of the first fluid passing through the heat sink 1220 of the thermoelectric module 1200 disposed outside the fluid flow portion 1100 will be described. Accordingly, in this specification, the fluid flow portion 1100 may be referred to as a duct or a cooling part. However, the embodiment of the present invention is not limited thereto, and the temperature of the second fluid flowing through the inside of the fluid flow portion 1100 may be higher than the temperature of the first fluid passing through the heat sink 1220 of the thermoelectric module 1200 disposed outside the fluid flow portion 1100.

For convenience of explanation, in this specification, a direction parallel to a direction in which the first fluid flows is defined as a first direction, a direction parallel to a direction in which the second fluid flows is defined as a second direction, and a direction of stacking between the fluid flow portion 1100 and the thermoelectric module 1200 is defined as a third direction.

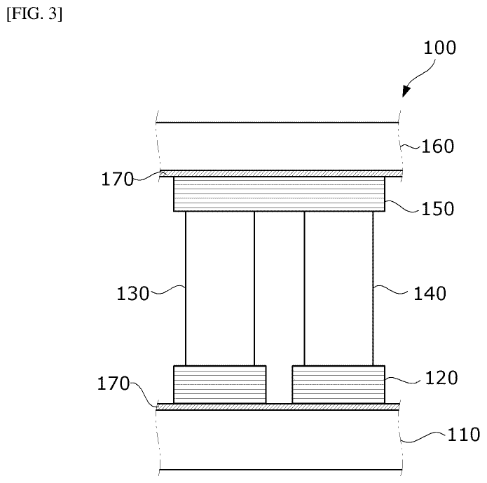

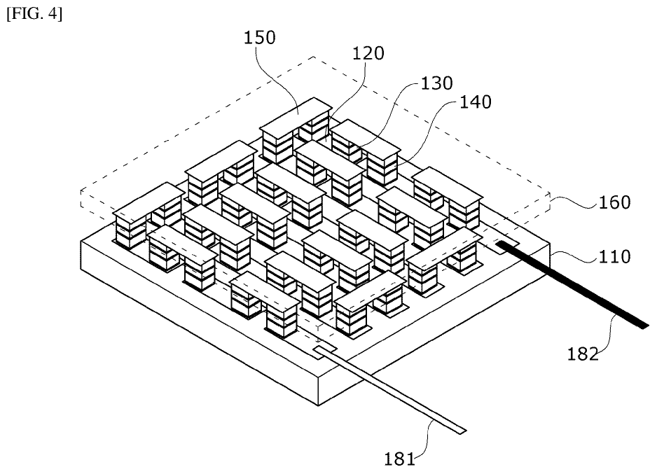

According to the embodiment of the present invention, the thermoelectric module 1200 includes a thermoelectric element 1210 and the heat sink 1220 disposed on the thermoelectric element 1210. The thermoelectric element 1210 according to the embodiment of the present invention may have a structure of a thermoelectric element 100 exemplified in FIGS. 3 and 4.

Referring to FIGS. 3 and 4, the thermoelectric element 100 includes a first substrate 110, a first electrode 120, a P-type thermoelectric leg 130, an N-type thermoelectric leg 140, a second electrode 150, and a second substrate 160.

The first electrode 120 is disposed between the first substrate 110 and lower bottom surfaces the P-type thermoelectric leg 130 and the N-type thermoelectric leg 140, and the second electrode 150 is disposed between the second substrate 160 and upper bottom surfaces of the P-type thermoelectric leg 130 and the N-type thermoelectric leg 140. Accordingly, a plurality of P-type thermoelectric legs 130 and a plurality of N-type thermoelectric legs 140 are electrically connected by the first electrode 120 and the second electrode 150. A pair of a P-type thermoelectric leg 130 and an N-type thermoelectric leg 140 that are electrically connected and disposed between the first electrode 120 and the second electrode 150 may form a unit cell.

For example, when a voltage is applied to the first electrode 120 and the second electrode 150 through lead wires 181 and 182, due to the Peltier effect, a substrate through which a current flows from the P-type thermoelectric leg 130 to the N-type thermoelectric leg 140 absorbs heat and may act as a cooling part, and a substrate through which a current flows from the N-type thermoelectric leg 140 to the P-type thermoelectric leg 130 is heated and may act as a heating part. Alternatively, when a temperature difference is applied between the first electrode 120 and the second electrode 150, charges within the P-type thermoelectric leg 130 and the N-type thermoelectric leg 140 may move due to the Seebeck effect, and electricity may be generated.

Here, the P-type thermoelectric leg 130 and the N-type thermoelectric leg 140 may be bismuth telluride (Bi—Te)-based thermoelectric legs containing bismuth (Bi) and tellurium (Te) as main raw materials. The P-type thermoelectric leg 130 may be a bismuth telluride (Bi—Te)-based thermoelectric leg including at least one of antimony (Sb), nickel (Ni), aluminum (Al), copper (Cu), silver (Ag), lead (Pb), boron (B), gallium (Ga), tellurium (Te), bismuth (Bi), and indium (In). For example, the P-type thermoelectric leg 130 may include 99 to 99.999 wt % of Bi—Sb—Te as a main raw material with respect to 100 wt % of the total weight, and may include 0.001 to 1 wt % of at least one of nickel (Ni), aluminum (Al), copper (Cu), silver (Ag), lead (Pb), boron (B), gallium (Ga), and indium (In). The N-type thermoelectric leg 140 may be a bismuth telluride (Bi—Te)-based thermoelectric leg including at least one of selenium (Se), nickel (Ni), aluminum (Al), copper (Cu), silver (Ag), lead (Pb), boron (B), gallium (Ga), tellurium (Te), bismuth (Bi), and indium (In). For example, the N-type thermoelectric leg 140 may include 99 to 99.999 wt % of Bi—Se—Te as a main raw material with respect to 100 wt % of the total weight, and may include 0.001 to 1 wt % of at least one of nickel (Ni), aluminum (Al), copper (Cu), silver (Ag), lead (Pb), boron (B), gallium (Ga), and indium (In).

The P-type thermoelectric leg 130 and the N-type thermoelectric leg 140 may be formed in a bulk or laminated form. Generally, a bulk P-type thermoelectric leg 130 or a bulk N-type thermoelectric leg 140 may be obtained through a process of heat-treating a thermoelectric material to manufacture an ingot, crushing and sieving the ingot to obtain powder for a thermoelectric leg, sintering the powder, and cutting the sintered body. In this case, the P-type thermoelectric leg 130 and the N-type thermoelectric leg 140 may be polycrystalline thermoelectric legs. In this way, when the P-type thermoelectric leg 130 and the N-type thermoelectric leg 140 are polycrystalline thermoelectric legs, the strength of the P-type thermoelectric leg 130 and the N-type thermoelectric leg 140 may be increased. A laminated P-type thermoelectric leg 130 or a laminated N-type thermoelectric leg 140 may be obtained through a process of applying a paste containing a thermoelectric material on a sheet-shaped base material to form a unit member, and then laminating and cutting the unit members.

In this case, the pair of the P-type thermoelectric leg 130 and the N-type thermoelectric leg 140 may have the same shape and volume, or may have different shapes and volumes. For example, since electrical conduction characteristics of the P-type thermoelectric leg 130 and the N-type thermoelectric leg 140 are different, a height or cross-sectional area of the N-type thermoelectric leg 140 may be formed differently from a height or cross-sectional area of the P-type thermoelectric leg 130.

In this case, the P-type thermoelectric leg 130 or the N-type thermoelectric leg 140 may have a cylindrical shape, a polygonal column shape, an elliptical column shape, or the like.

In this specification, the thermoelectric leg may also be referred to as a thermoelectric structure, a semiconductor element, a semiconductor structure, or the like.

The performance of the thermoelectric element according to the embodiment of the present invention may be expressed by a figure of merit ZT. The figure of merit ZT may be expressed as illustrated in Equation 1.

$$ZT = {α}^{2} \cdot σ \cdot T / k \qquad [ Equation 1 ]$$

Here, α is a Seebeck coefficient [V/K], σ is an electrical conductivity [S/m], and α²σ is a power factor ([W/mK²]). Additionally, T is a temperature, k is a thermal conductivity [W/mK], and k may be expressed as a·cp·ρ, wherein a is a thermal diffusivity [cm²/S], cp is a specific heat [J/gK], and p is a density [g/cm³].

To obtain the figure of merit ZT of the thermoelectric element, a Z value (V/K) is measured using a Z meter, and the figure of merit ZT may be calculated using the measured Z value.

Here, the first electrode 120 disposed between the first substrate 110 and the P-type thermoelectric leg 130 and the N-type thermoelectric leg 140, and the second electrode 150 disposed between the second substrate 160 and the P-type thermoelectric leg 130 and the N-type thermoelectric leg 140 include at least one of copper (Cu), silver (Ag), aluminum (Al), and nickel (Ni) and may have a thickness of 0.01 mm to 0.3 mm. When the thickness of the first electrode 120 or the second electrode 150 is less than 0.01 mm, a function as an electrode may deteriorate and the electrical conductivity performance may be reduced, and when the thickness exceeds 0.3 mm, the conductivity efficiency may be reduced due to an increase in resistance.

Additionally, the first substrate 110 and the second substrate 160 that face each other may be metal substrates, and a thickness thereof may be 0.1 mm to 1.5 mm. When the thickness of the metal substrate is less than 0.1 mm or more than 1.5 mm, heat dissipation characteristics or thermal conductivity may become excessively high, which may deteriorate the reliability of the thermoelectric element. In addition, when the first substrate 110 and the second substrate 160 are metal substrates, an insulating layer 170 may be further formed between the first substrate 110 and the first electrode 120 and between the second substrate 160 and the second electrode 150. The insulating layer 170 may include a material having a thermal conductivity of 1 to 20 W/mK. In this case, the insulating layer 170 may be a layer formed of a resin composition including at least one of an epoxy resin and a silicone resin, and an inorganic material or a silicone composite including silicone and an inorganic material, or an aluminum oxide layer. Here, the inorganic material may be at least one of an oxide, nitride and carbide of aluminum, boron, silicon, or the like.

In this case, sizes of the first substrate 110 and the second substrate 160 may be formed differently. That is, the volume, thickness, or area of one of the first substrate 110 and the second substrate 160 may be formed to be larger than the volume, thickness, or area of the other. Here, the thickness may be a thickness in a direction from the first substrate 110 toward the second substrate 160, and the area may be an area in a direction perpendicular to the direction from the first substrate 110 toward the second substrate 160. Accordingly, the heat absorption performance or heat dissipation performance of the thermoelectric element can be improved. Preferably, the volume, thickness or area of the first substrate 110 may be formed to be larger than at least one of the volume, thickness, or area of the second substrate 160. In this case, when the first substrate 110 is disposed in a high temperature region for the Seebeck effect, when the first substrate 110 is applied to a heating region for the Peltier effect, or when a sealing member for protecting the thermoelectric element from an external environment which will be described below is disposed on the first substrate 110, the first substrate 110 may have at least one of a volume, thickness, and area larger than that of the second substrate 160. In this case, the area of the first substrate 110 may be formed in a range of 1.2 to 5 times the area of the second substrate 160. When the area of the first substrate 110 is formed to be less than 1.2 times that of the second substrate 160, the effect of improving heat transfer efficiency is not significant, and when the area of the first substrate 110 exceeds 5 times, the heat transfer efficiency is significantly reduced, and it may be difficult to maintain a basic shape of the thermoelectric module.

In addition, a heat dissipation pattern, for example, an uneven pattern, may be formed on the surface of at least one of the first substrate 110 and the second substrate 160. Thus, the heat dissipation performance of the thermoelectric element can be improved. When the uneven pattern is formed on the surface that comes into contact with the P-type thermoelectric leg 130 or the N-type thermoelectric leg 140, bonding characteristics between the thermoelectric leg and the substrate can also be improved.

Although not illustrated, a sealing member may be additionally disposed between the first substrate 110 and the second substrate 160. The sealing member may be disposed on the side surfaces of the first electrode 120, the P-type thermoelectric leg 130, the N-type thermoelectric leg 140, and the second electrode 150 between the first substrate 110 and the second substrate 160. Thus, the first electrode 120, the P-type thermoelectric leg 130, the N-type thermoelectric leg 140, and the second electrode 150 may be sealed from external moisture, heat, contamination, and the like.

Referring again to FIGS. 1 and 2, the thermoelectric module 1200 according to the embodiment of the present invention includes the thermoelectric element 1210 and the heat sink 1220 disposed on the thermoelectric element 1210. In FIGS. 1 and 2, two thermoelectric modules 1200-1 and 1200-2 are disposed on the first surface 1110 of the fluid flow portion 1100, and two thermoelectric modules 1200-3 and 1200-4 are disposed on the second surface 1120, but the present invention is not limited thereto, and two or more thermoelectric modules may be disposed on one surface.

As described above, each of the thermoelectric elements 1210 includes the first substrate 110 disposed in contact with the fluid flow portion 1100, a plurality of first electrodes 120 disposed on the first substrate 110, a plurality of thermoelectric legs 130 and 140 disposed on the plurality of first electrodes 120, a plurality of second electrodes 150 disposed on the plurality of thermoelectric legs 130 and 140, and the second substrate 160 disposed on the plurality of second electrodes 150, and the heat sink 1220 is disposed on the second substrate 160. Additionally, an insulating layer 170 may be further disposed between the first substrate 110 and the plurality of first electrodes 120 and between the plurality of second electrodes 150 and the second substrate 160.

In this case, the first substrate 110 of the thermoelectric element 1210 disposed on the fluid flow portion 1100 may be a metal substrate, and the metal substrate may be bonded to the surface of the fluid flow portion 1100 by a thermal interface material (TIM, not illustrated). Since the metal substrate has excellent heat transfer performance, heat transfer between the thermoelectric element and the fluid flow portion 1100 is easily performed. In addition, when the metal substrate and the fluid flow portion 1100 are bonded to each other by the TIM, heat transfer between the metal substrate and the fluid flow portion 1100 may not be hindered. Here, the metal substrate may be one of a copper substrate, an aluminum substrate, and a copper-aluminum substrate, but is not limited thereto. In this specification, the first substrate of the thermoelectric element 1210 disposed on the fluid flow portion 1100 may be referred to as the first substrate 110 or the first substrate 1212.

As described above, according to the embodiment of the present invention, a plurality of thermoelectric modules 1200 are disposed on the surface of the fluid flow portion 1100. Each of the plurality of thermoelectric modules 1200 may include a connector for extracting the produced electricity externally or for applying electricity to use as a Peltier.

According to the embodiment of the present invention, it is intended to accommodate a maximum number of thermoelectric devices in a limited space by changing positions of connectors, thereby improving a power generation capacity.

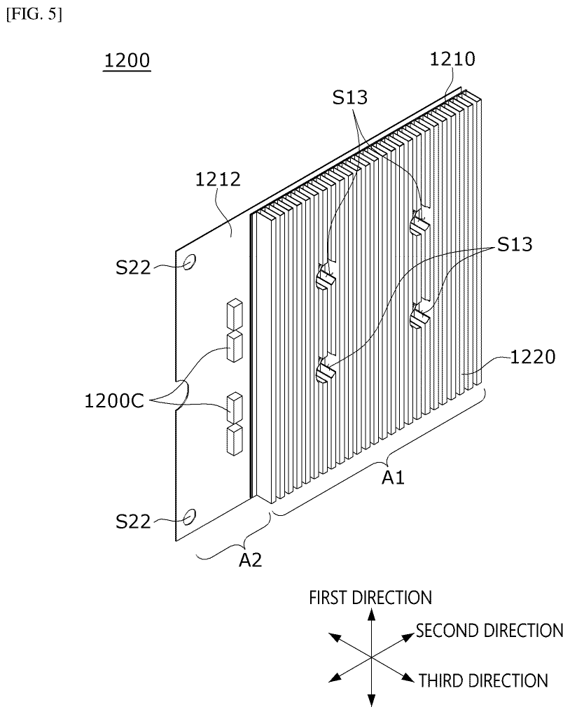

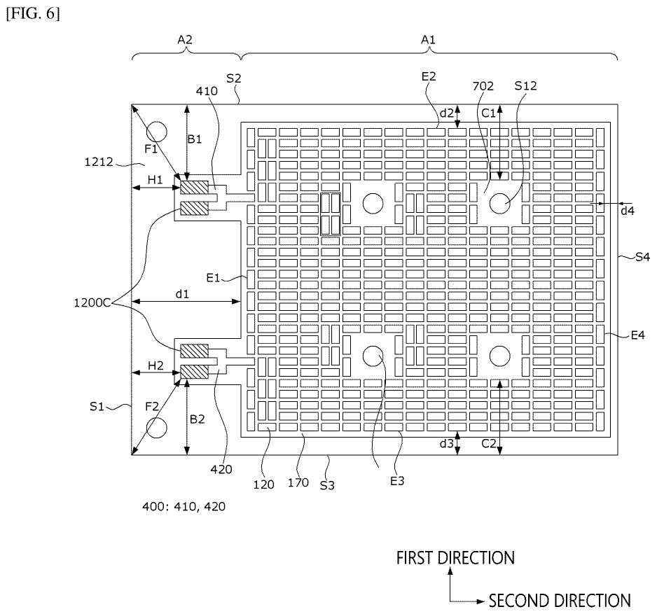

FIG. 5 is a perspective view of the thermoelectric module according to an embodiment of the present invention, and FIG. 6 is an exemplary view of the first substrate and the first electrode in the thermoelectric module according to the embodiment of FIG. 5.

Referring to FIGS. 1 to 6, the thermoelectric device 1000 according to the embodiment of the present invention includes the fluid flow portion 1100, and the first thermoelectric module 1200-1 and the second thermoelectric module 1200-2 disposed on the fluid flow portion 1100 in the third direction, and the first thermoelectric module 1200-1 and the second thermoelectric module 1200-2 are disposed in the second direction perpendicular to the third direction, and the first fluid passes through heat sinks 1220-1 and 1220-2 in the first direction.

Each of the first thermoelectric module 1200-1 and the second thermoelectric module 1200-2 includes the thermoelectric element 1210 disposed on the fluid flow portion 1100, and the heat sink 1220 disposed on the first thermoelectric element 1210 in the third direction, and also includes a connector 1200C electrically connected to the thermoelectric element 1210.

The first substrate 1212 of the thermoelectric element 1210 is disposed on the first surface 1110 of the fluid flow portion 1100. In this case, the first substrate 1212 may be disposed in direct contact with the first surface 1110 of the fluid flow portion 1100, or may be disposed in indirect contact with the first surface 1110 through the TIM, or the like. The first substrate 1212 may be the first substrate 110 described with reference to FIGS. 1 to 4. Accordingly, with respect to the first substrate 1212, duplicate descriptions of the same content as the first substrate 110 described with reference to FIGS. 1 to 4 will be omitted.

The first substrate 1212 of the thermoelectric module 1200 may include a first region A1 and a second region A2. In this case, the plurality of first electrodes, the plurality of thermoelectric legs, the plurality of second electrodes, the second substrate, and the heat sink 1220 are disposed in the first region A1, and a connector 1200C connected to the first electrode is disposed in the second region A2 which is one side of the first region A1. Here, the second region A2 may be disposed on a side portion of the first region A1 in the second direction when a direction in which the first fluid moves is referred to as the first direction. Here, the plurality of first electrodes, the plurality of thermoelectric legs, the plurality of second electrodes, and the second substrate may be the plurality of first electrodes 120, the plurality of thermoelectric legs 130 and 140, the plurality of second electrodes 150, and the second substrate 160 described with reference to FIGS. 1 to 4.

According to the embodiment of the present invention, the fluid flow portion 1100 and the thermoelectric module 1200 may be coupled by a coupling member (not illustrated). To this end, a plurality of 1-1 through holes S11 may be formed in the first surface 1110 of the fluid flow portion 1100, and a plurality of 1-2 through holes S12 corresponding to the plurality of 1-1 through holes S11 may also be formed in the first region A1 on the first substrate 1212 of the thermoelectric module 1200. In addition, a plurality of 1-3 through holes S13 corresponding to the plurality of 1-1 through holes S11 and the plurality of 1-2 through holes S12 may be formed in the second substrate (not illustrated) and the heat sink 1220 of the thermoelectric module 1200. Thus, a plurality of coupling members (not illustrated) are coupled to the plurality of 1-1 through holes S13, the plurality of 1-2 through holes S12, and the plurality of 1-3 through holes S13, and thus, the fluid flow portion 1100 and the thermoelectric module 1200 can be coupled.

Meanwhile, according to the embodiment of the present invention, a plurality of 2-1 through holes S21 may be further formed in the first surface 1110 of the fluid flow portion 1100, and a plurality of 2-2 through holes S22 corresponding to the plurality of 2-1 through holes S21 may be further formed in the second region A2 on the first substrate 1212 of the thermoelectric module 1200. The plurality of coupling members (not illustrated) are coupled to the plurality of 2-1 through holes S21 and the plurality of 2-2 through holes S22, and thus the fluid flow portion 1100 and the thermoelectric module 1200 can be coupled.

Accordingly, since not only the first region A1 on the first substrate 1212 of the thermoelectric module 1200 but also the second region A2 can be coupled to the fluid flow portion 1100, the entire first substrate 1212 of the thermoelectric module 1200 can have an even bonding force with respect to the fluid flow portion 1100, and heat can be evenly distributed over the entire first substrate 1212.

Meanwhile, according to the embodiment of the present invention, the connector 1200C is disposed on the first substrate 1212 of the thermoelectric element 1210, and is disposed on a side portion of the thermoelectric element 1210 in the second direction, that is, on a side portion of the thermoelectric element 1210 in the second direction on the first substrate 1212.

Accordingly, since the connector 1200C is not disposed within a path of the first fluid passing through the heat sink 1220, a problem of heat of the first fluid being lost in a region in which the connector 1200C is disposed before passing through the heat sink 1220 can be prevented, and a problem of a differential pressure of the first fluid passing through the heat sink 1220 increasing due to a region in which the connector 1200C is disposed can be prevented.

As illustrated in FIGS. 1 and 2, when the first thermoelectric module 1200-1 and the second thermoelectric module 1200-2 are disposed in the second direction on the first surface 1110 of the fluid flow portion 1100, a connector 1200-1C of the first thermoelectric module 1200-1 is disposed on the first side in the second direction with respect to the thermoelectric element 1210-1 of the first thermoelectric module 1200-1, and a connector 1200-2C of the second thermoelectric module 1200-2 is disposed on the second side in the second direction with respect to the thermoelectric element 1210-2 of the second thermoelectric module 1200-2, and the first side and the second side may be in opposite directions.

Accordingly, even when a plurality of thermoelectric modules are disposed on the first surface 1110 of the fluid flow portion 1100, the connector may not be disposed on the path of the first fluid passing through the heat sink 1220.

Meanwhile, in this specification, withstand voltage performance may be a characteristic that is maintained without insulation breakdown for a predetermined period of time under a predetermined voltage and a predetermined current. For example, when it is maintained without insulation breakdown for 10 seconds under a voltage of AC 2.5 kV and a current of 1 mA, the withstand voltage can be said to be 2.5 kV.

Meanwhile, since a power source is generally connected to the electrode disposed on the low temperature part side of the thermoelectric element 1210, higher withstand voltage performance may be required on the low temperature part side than on the high temperature part side. Hereinafter, a plurality of first electrodes 120 and a terminal electrode 400 disposed on the first substrate 1212 will be described. The above-described connector 1200C may be disposed on the terminal electrode 400.

As described above, a first insulating layer 170 is disposed on the first substrate 1212, and the plurality of first electrodes 120 are disposed on the first insulating layer 170.

In this case, the plurality of first electrodes 120 may be disposed to form a plurality of electrode edges, and the first substrate 1212 may have a plurality of substrate edges corresponding to the plurality of electrode edges. Here, the electrode edges may mean edges of the plurality of first electrodes 120, and the substrate edge may mean an edge of the first substrate 1212. For example, when the plurality of first electrodes 120 are disposed in a quadrangular shape, the plurality of first electrodes 120 may have first to fourth electrode edges E1 to E4, and the first substrate 1212 may have first to fourth substrate edges S1 to S4 respectively corresponding to the first to fourth electrode edges E1 to E4.

According to the embodiment of the present invention, the terminal electrode 400 is an electrode for connecting a wire and may be disposed on the same plane as the plurality of first electrodes 120 on the first insulating layer 170. Thus, the terminal electrode 400 may be expressed as a configuration included in the plurality of first electrodes 120, that is, as one of the plurality of first electrodes 120. Alternatively, the terminal electrode 400 may be expressed as being disposed between the plurality of first electrodes 120 to be directly or indirectly connected to at least one of the plurality of first electrodes 120.

The terminal electrode 400 may be divided into a first terminal electrode 410 and a second terminal electrode 420, and each of the terminal electrodes 410 and 420 may include an extension portion that extends from an effective region toward one of the first to fourth substrate edges S1 to S4 to be electrically connected to the connector 1200C. Here, the extension portion may be a region included in the terminal electrode 410 and 420 and in which the connector 1200C is disposed. Alternatively, the extension portion may be the terminal electrodes 410 and 420 themselves, and thus the extension portion and the terminal electrodes 410 and 420 may be used interchangeably. In this case, according to a connection type between adjacent elements, such as series, parallel, or series-parallel, the extension portions of the first terminal electrode 410 and the second terminal electrode 420 may branch into one or more portions and then extend. In this specification, the effective region may be defined as a region in which the plurality of first electrodes and the plurality of second electrodes vertically overlap, that is, a region in which the plurality of P-type thermoelectric legs 140 and N-type thermoelectric legs 150 are disposed to substantially implement the Peltier effect or the Seebeck effect. The connector 1200C may be disposed on each of the extension portions of the first terminal electrode 410 and the second terminal electrode 420, and each of the connectors 1200C may be a connector device that electrically connects the terminal electrodes 410 and 420 with an external terminal. For example, at least one (−) terminal is connected to the first connector on the extension portion of the first terminal electrode 410, at least one (+) terminal may be connected to the second connector on the extension portion of the second terminal electrode 420, but the extension portion of each of the terminal electrodes 410 and 420 and the number of connectors, an arrangement form, and polarity of the external terminal are not limited thereto.

Each of the first terminal electrode 410 and the second terminal electrode 420 may be electrically connected directly or indirectly to one of the plurality of first electrodes 120 or second electrodes 160. When each of the first terminal electrode 410 and the second terminal electrode 420 is directly or indirectly connected to one of the plurality of first electrodes 120 or second electrodes 160, positions of the terminal electrodes 410 and 420 may affect insulation resistance of the thermoelectric element. The insulation resistance means electrical resistance that an insulator exhibits when a certain voltage is applied, and when a thermoelectric element is exposed to a high voltage environment or when a plurality of thermoelectric elements are connected and driven, a specified insulation resistance has to be satisfied. For example, a thermoelectric element has to satisfy a requirement of having an insulation resistance of 500 MΩ or more when a dc voltage of 500 V is applied.

According to the embodiment of the present invention, it is intended to improve an insulation resistance utilizing the position of the terminal electrode 400. Hereinafter, the terminal electrode 400 means the first terminal electrode 410 or the second terminal electrode 420.

According to the embodiment of the present invention, when the terminal electrode 400 is connected to some of the plurality of first electrodes 120 disposed on the first electrode edge E1, or is disposed between the plurality of first electrodes 120 disposed on the first electrode edge E1, a distance d1 between the first electrode edge E1 and the first substrate edge S1 may be longer than distances d2 to d4 between the second to fourth electrode edges E2 to E4 and the second to fourth substrate edges S2 to S4.

Here, a shortest distance H1 between the terminal electrode 400 and the first substrate edge S1 may be 12 mm or more, preferably 14 mm or more, and more preferably 16 mm or more.

Additionally, each of a shortest distance B1 between the second substrate edge S2 connected to the first substrate edge S1 and the terminal electrode 400 and a shortest distance B2 between the third substrate edge S3 connected to the first substrate edge S1 and the terminal electrode 401 may be 12 mm or more, preferably 14 mm or more, and more preferably 16 mm or more.

Alternatively, each of a shortest distance F1 from a point at which the first substrate edge S1 and the second substrate edge S2 meet, that is, a vertex between the first substrate edge S1 and the second substrate edge S2 to the terminal electrode 410, and a shortest distance F2 from a point at which the first substrate edge S1 and the third substrate edge S3 meet, that is, a vertex between the first substrate edge S1 and the third substrate edge S3 to the terminal electrode 420 may be 12 mm or more, preferably 14 mm or more, and more preferably 16 mm or more.

In this way, a thermoelectric element having an insulation resistance of 500 MΩ or more under a dc voltage of 500 V can be obtained by controlling the distance between the substrate edge and the terminal electrode 400.

More specifically, a ratio of the distance d1 between the first electrode edge E1 and the first substrate edge S1 to the distances H1, B1, F1, H2, B2, and F2 between the substrate edge and the terminal electrode 400 may be 1.2 to 2.5. That is, the shortest distance d1 between the effective region and the first substrate edge S1 may be 1.2 to 2.5 times the shortest distances H1 and H2 between an end of the terminal electrode 400 and the first substrate edge S1. Here, the effective region may mean a region in which the plurality of first electrodes 120 and the plurality of second electrodes 160 vertically overlap. For example, when the shortest distance H1 between the terminal electrode 400 and the first substrate edge S1 is 12 mm, the distance d1 between the first electrode edge E1 and the first substrate edge S1 may be 14.5 to 30 mm. When the ratio of the distance d1 between the first electrode edge E1 and the first substrate edge S1 to the distances H1, B1, F1, H2, B2, and F2 between the substrate edge and the terminal electrode 400 is less than 1.2, a spark may occur due to a short circuit between the connector 1200C disposed on the terminal electrode 400 and the plurality of first electrodes 120 disposed along the first electrode edge E1. On the other hand, when the ratio of the distance d1 between the first electrode edge E1 and the first substrate edge S1 to the distances H1, B1, F1, H2, B2, and F2 between the substrate edge and the terminal electrode 400 exceeds 2.5, since an area of the effective region, that is, a region in which the thermoelectric legs can be disposed, is substantially narrowed, when the thermoelectric module is a power generation module that utilizes the Seebeck effect, a power generation amount may be reduced.

As described above, the 1-2 through hole S12 may be formed in the first substrate 1212. In this case, a shortest distance from an edge of the 1-2 through hole S12 to the plurality of first electrodes 120 may be 8 mm or more, preferably 8 mm to 12 mm, more preferably 8 mm to 10 mm, and even more preferably 8 mm to 9 mm. In this case, the shortest distance from the edge of the 1-2 through hole S12 to the plurality of first electrodes 120 may be 50 times or more, preferably 50 to 180 times a thickness of the first insulating layer 170. Thus, even when a spark occurs at the electrode under high voltage, a sufficient insulation distance can be secured not to affect the substrate, and thus a thermoelectric element having high withstand voltage performance can be obtained.

In this case, a plurality of 1-2 through holes S12 may be formed in the first substrate 1212, and thus, a plurality of hole arrangement regions 702 may also be formed. For example, the first substrate 1212 may include four 1-2 through holes S12 and four hole arrangement regions 702. Here, the hole arrangement region 702 may be defined as a space formed by a virtual line connecting surfaces of the electrodes that are most adjacent to the 1-2 through hole S12 and are adjacent to each other. The hole arrangement region 702 may be formed in a polygonal shape, and preferably in a quadrangular shape. The plurality of first electrodes 120 may not be disposed within the hole arrangement region 702.

Meanwhile, an area of the hole arrangement region 702 may be at least four times, preferably at least six times, and more preferably at least eight times an area of one first electrode 120. When the area of the hole arrangement region 702 is less than four times the area of one first electrode 120, under a high voltage of AC 1 kV or higher, a current may move to the first substrate 1212 through the 1-2 through hole S12, which causes electrical breakdown of the thermoelectric module. Therefore, in applications under high voltage, it is important to secure a sufficient insulation distance to prevent electrical breakdown of the thermoelectric module. When the area of the hole arrangement region 702 is eight times or more the area of one first electrode 120, no electrical breakdown occurs even under a high voltage of AC 2.5 kV or higher.

Meanwhile, according to FIGS. 1 to 6, each of the thermoelectric elements is illustrated as including one first substrate, one second substrate, and one heat sink, but is not limited thereto.

Each of the thermoelectric elements may include a plurality of second substrates and a plurality of heat sinks for one first substrate 1212.

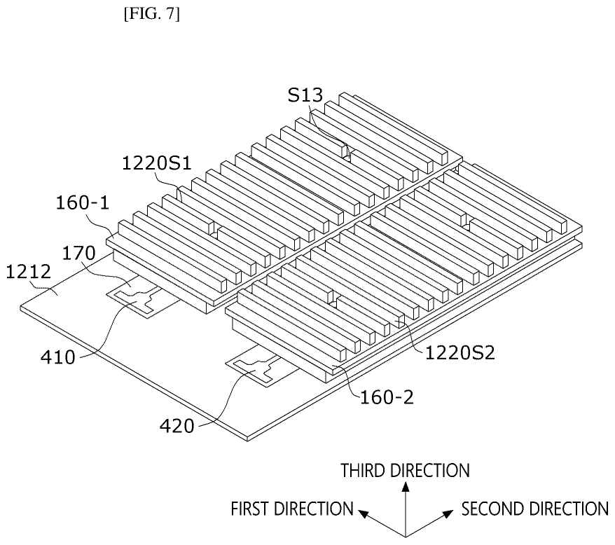

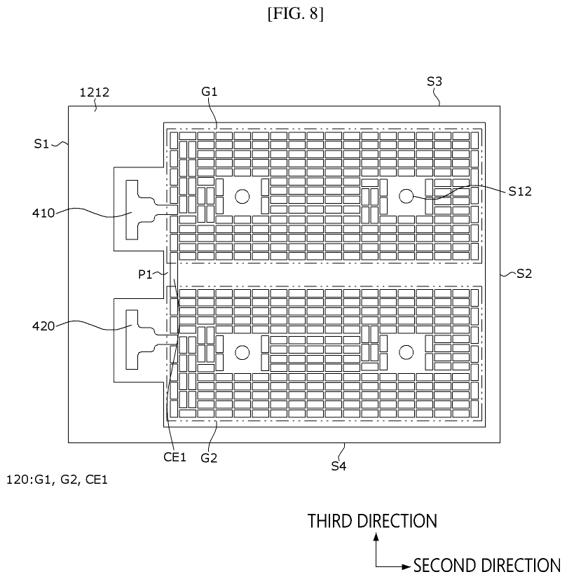

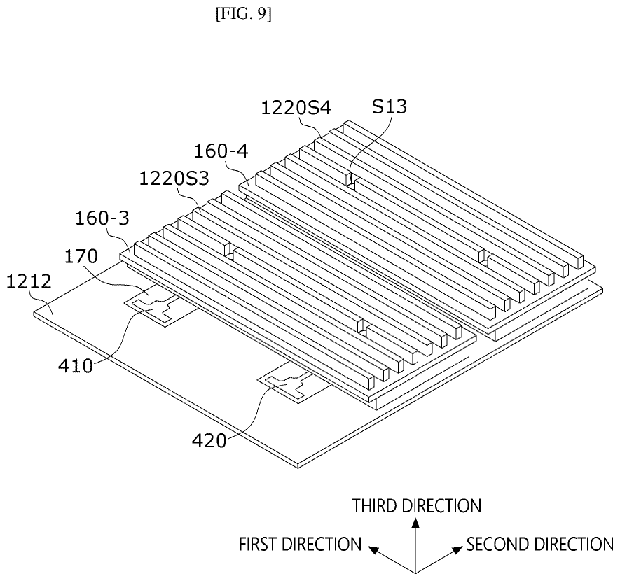

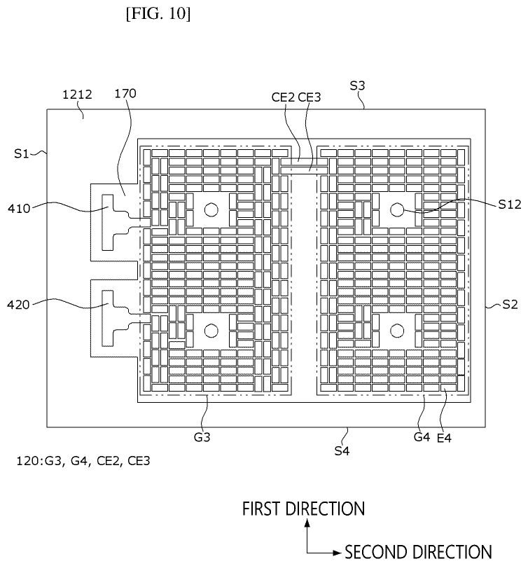

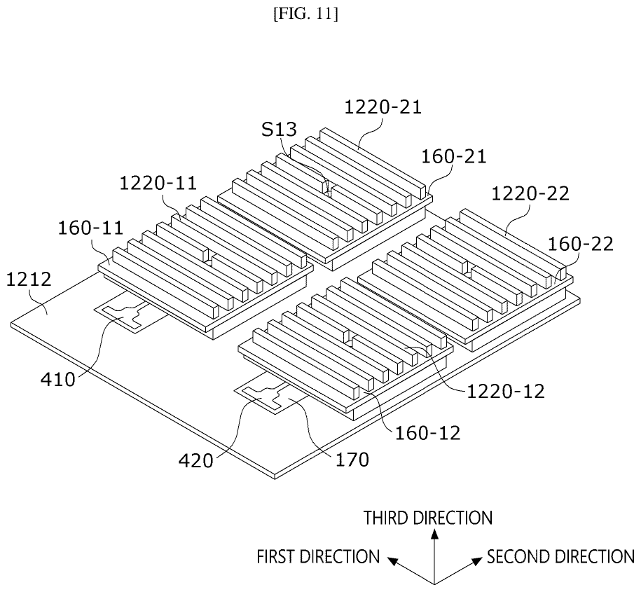

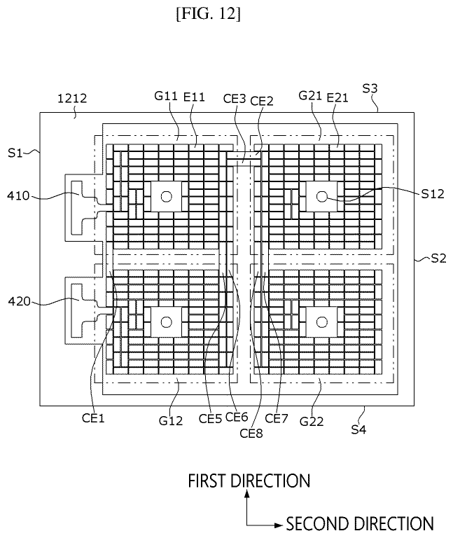

FIG. 7 is a perspective view of a thermoelectric module according to another embodiment of the present invention, FIG. 8 is an exemplary view of a first substrate and a first electrode in the thermoelectric module according to the embodiment of FIG. 7, FIG. 9 is a perspective view of a thermoelectric module according to still another embodiment of the present invention, FIG. 10 is an exemplary diagram of a first substrate and a first electrode in the thermoelectric module according to the embodiment of FIG. 9, FIG. 11 is a perspective view of a thermoelectric module according to yet another embodiment of the present invention, and FIG. 12 is an example diagram of a first substrate and a first electrode in the thermoelectric module according to the embodiment of FIG. 11.

Referring to FIGS. 7 to 12, in order to reduce bending of the substrate on the high temperature part side, a second substrate portion 160 may be configured of a plurality of divided substrates for one first substrate 1212.

For example, the second substrate portion 160 may be divided in the second direction as illustrated in FIG. 7, divided in the first direction as illustrated in FIG. 9, or divided along the first and second directions as illustrated in FIG. 11.

According to the embodiment of the present invention, the plurality of first electrodes 120 may be disposed on one first substrate 1212 according to a division direction or division position of the second substrate portion 160. Accordingly, even when the second substrate portion 160 includes a plurality of second substrates disposed to be spaced apart from each other, the plurality of first electrodes 120, the semiconductor structure, and the plurality of second electrodes can be electrically connected using the pair of terminal electrodes 410 and 420, and since it is possible to accommodate the maximum number of semiconductor structures per unit area, it is possible to provide high thermoelectric performance.

Referring to FIGS. 8, 10, and 12, a plurality of first electrodes 120 are disposed on an insulating layer 170, and the plurality of first electrodes 120 may be divided into a plurality of electrode groups.

For example, as illustrated in FIGS. 7 and 8, when the second substrate portion 160 includes a 2-1 substrate 160-1 and a 2-2 substrate 160-2 that are disposed to be spaced apart from each other in the second direction, a first electrode group G1 may be disposed to vertically overlap the 2-1 substrate 160-1, and a second electrode group G2 may be disposed to vertically overlap the 2-2 substrate 160-2. According to this, the first electrode group G1 and the second electrode group G2 may be divided between the third outer side S3 and the fourth outer side S4 of the first substrate 1212.

The first terminal electrode 410 is disposed on the first electrode group G1 side, the second terminal electrode 420 is disposed on the second electrode group G2 side, and the first electrode group G1 and the second electrode group G2 may be connected by a connection electrode CE1. The first electrode group G1 and the second electrode group G2 may each include a plurality of first electrodes, and the connection electrode CE1 may be disposed in a row closest to the first terminal electrode 410 and the second terminal electrode 420 among the plurality of first electrodes in the first electrode group G1 and the second electrode group G2. A long side of the connection electrode CE1 is longer than a long side of each of the first electrodes, and at least a part of the connection electrode CE1 may not vertically overlap the 2-1 substrate 160-1 and the 2-2 substrate 160-2. That is, at least a part of the connection electrode CE1 is disposed within a spacing region between the 2-1 substrate 160-1 and the 2-2 substrate 160-2, and may connect the first electrode group G1 with the second electrode group G2.

As illustrated in FIGS. 9 and 10, when the second substrate portion 160 includes a 2-3 substrate 160-3 and a 2-4 substrate 160-4 that are disposed to be spaced apart from each other in the first direction, a third electrode group G3 may be disposed to vertically overlap the 2-3 substrate 160-3, and a fourth electrode group G4 may be disposed to vertically overlap the 2-4 substrate 160-4. Accordingly, the third electrode group G3 and the fourth electrode group G4 may be divided between the first outer side S1 and the second outer side S2 of the first substrate 1212.

Here, both the first terminal electrode 410 and the second terminal electrode 420 may be disposed on the third electrode group G3 side, and two connection electrodes CE2 and CE3 disposed adjacent to each other may connect the third electrode group G3 with the fourth electrode group G4. The two connection electrodes CE2 and CE3 may be a connection electrode CE2 and a connection electrode CE3 disposed adjacent to the connection electrode CE2 and parallel to each other. In this specification, the fact that two connection electrodes are disposed adjacent and parallel to each other may mean that a long side of one of the two connection electrodes and a long side of the other are disposed adjacently and facing each other. That is, it may mean that the two connection electrodes are disposed parallel to each other in a direction of the long sides thereof. Although not illustrated, at least a part of the two connection electrodes CE2 and CE3 may not vertically overlap the 2-3 substrate 160-3 and the 2-4 substrate 160-4 and may be disposed in a spacing region between the 2-3 substrate 160-3 and the 2-4 substrate 160-4.

In this case, the two connection electrodes CE2 and CE3 may be disposed in two rows closest to the outermost row among the plurality of first electrodes in the third electrode group G3 and the fourth electrode group G4.

In FIG. 10, the two connection electrodes CE2 and CE3 are illustrated as being disposed in the two rows closest to the outermost row on the left side of the plurality of first electrodes in the third electrode group G3 and the fourth electrode group G4, but are not limited thereto. The two connection electrodes that connect two electrode groups divided between the first outer side S1 and the second outer side S2 of the first substrate 1212 may be disposed parallel to each other and adjacent to the two rows closest to the outermost row on the right side of the plurality of first electrodes within the two electrode groups.

Referring to FIGS. 11 and 12, when the second substrate portion 160 includes a 2-11 substrate 160-11, a 2-12 substrate 160-12, a 2-21 substrate 160-21, and a 2-22 substrate 160-22 disposed to be spaced apart from each other in the first direction and the second direction, an eleventh electrode group G11 may be disposed to vertically overlap a 2-11 substrate 380-11, a twelfth electrode group G12 may be disposed to vertically overlap a 2-12 substrate 380-12, a twenty-first electrode group G21 may be disposed to vertically overlap a 2-21 substrate 380-21, and a twenty-second electrode group G22 may be disposed to vertically overlap a 2-22 substrate 380-22. Accordingly, the eleventh electrode group G11 and the twelfth electrode group G12 may be separated from the twenty-first electrode group G21 and the twenty-second electrode group G22 between the first outer side S1 and the second outer side S2 of the first substrate 310, and the eleventh electrode group G11 and the twenty-first electrode group G21 may be separated from the twelfth electrode group G12 and the twenty-second electrode group G22 between the third outer side S3 and the fourth outer side S4 of the first substrate 310.

Here, the first terminal electrode 410 is disposed on the eleventh electrode group G11 side, the second terminal electrode 420 is disposed on the twelfth electrode group G12 side, and the eleventh electrode group G11 and the twelfth electrode group G12 may be connected by the connection electrode CE1. The eleventh electrode group G11 and the twelfth electrode group G12 may each include a plurality of first electrodes, and the connection electrode CE1 may be disposed in a row closest to the first terminal electrode 410 and the second terminal electrode 420 among the plurality of first electrodes in the eleventh electrode group G11 and the twelfth electrode group G12. Although not illustrated, at least a part of the connection electrode CE1 may be disposed to vertically overlap a spacing region between the 2-11 substrate 160-11 and the 2-12 substrate 160-12.

In addition, the two connection electrodes CE2 and CE3 disposed adjacent and parallel to each other may connect the eleventh electrode group G11 with the twenty-first electrode group G21. Although not illustrated, at least a part of the two connection electrodes CE2 and CE3 may be disposed not to vertically overlap the 2-11 substrate 160-11 and the 2-21 substrate 160-21 and to vertically overlap a spacing region between the 2-11 substrate 160-11 and the 2-21 substrate 160-21.

In this case, the two connection electrodes CE2 and CE3 may be disposed parallel to each other in two rows closest to the outermost row among a plurality of first electrodes E11 and E21 in the eleventh electrode group G11 and the twenty-first electrode group G21.

In FIG. 12, the two connection electrodes CE2 and CE3 are illustrated as being disposed in the two rows closest to the outermost row on the left side of the plurality of first electrodes in the eleventh electrode group G11 and the twenty-first electrode group G21, but are not limited thereto. The two connection electrodes that connects two electrode groups divided between the first outer side S1 and the second outer side S2 of the first substrate 1212 may be disposed parallel to each other in the two rows closest the outermost row on the right side of the plurality of first electrodes within the two electrode groups.

In addition, two connection electrodes CE5 and CE6 disposed adjacent and parallel to each other may connect the eleventh electrode group G11 with the twelfth electrode group G12. As described above, since the connection electrode CE1 is disposed in the row closest to the first terminal electrode 410 and the second terminal electrode 420 among the plurality of first electrodes E11 and E12 in the eleventh electrode group G11 and the twelfth electrode group G12, the two connection electrodes CE5 and CE6 may be disposed parallel to each other in the outermost row and the row closest thereto, which is disposed farthest from the first terminal electrode 410 and the second terminal electrode 420 among the plurality of first electrodes E11 and E12 in the eleventh electrode group G11 and the twelfth electrode group G12.

Similarly, two connection electrodes CE7 and CE8 disposed adjacent and parallel to each other may connect the twenty-first electrode group G21 with the twenty-second electrode group G22, and the two connection electrodes CE7 and CE8 may be disposed adjacent to each other in the outermost row and the row closest thereto among the plurality of first electrodes E21 and E22 in the twenty-first electrode group G21 and the twenty-second electrode group G22.

In the above, the embodiment in which the second substrate portion 160 is divided into two in the first direction or into two in the second direction has been described, but this can also be applied to an embodiment in which the second substrate portion 160 is divided into two or more in the first direction or into two or more in the second direction.

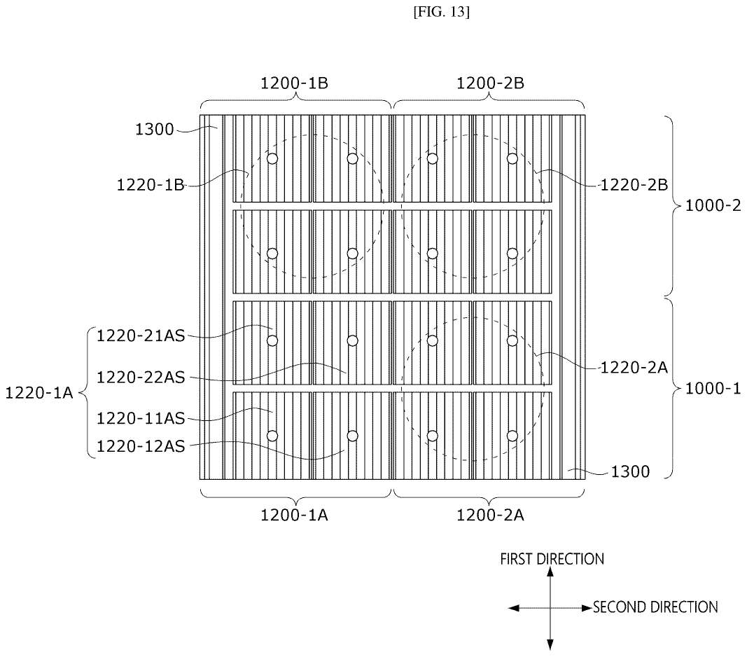

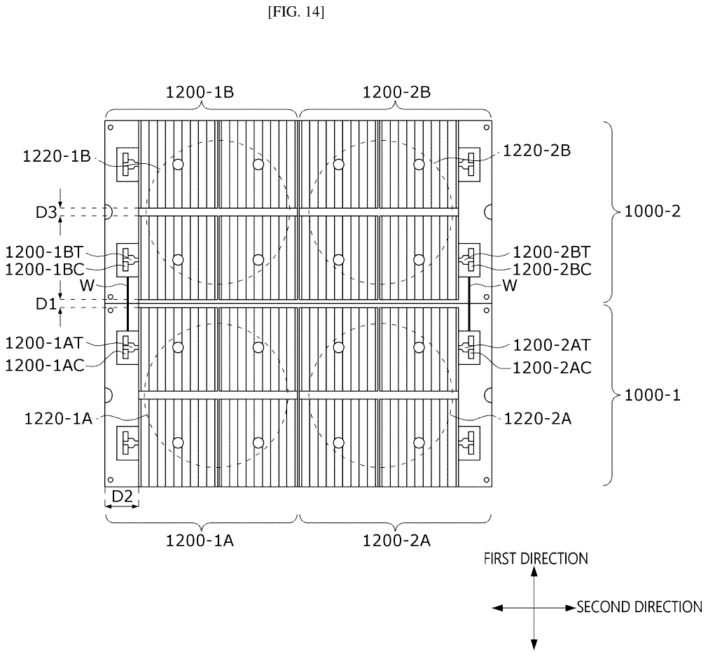

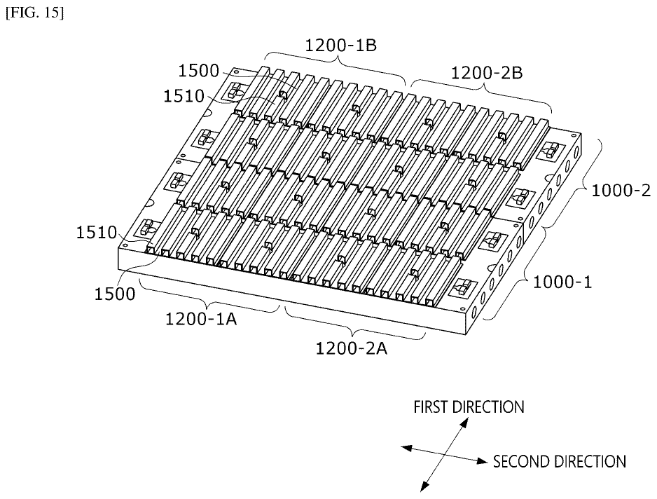

FIG. 13 is a plan view of a thermoelectric module array according to an embodiment of the present invention, and FIGS. 14 and 15 are a plan view and a perspective view of the thermoelectric module array of FIG. 13 from which a shield member is removed.

Referring to FIGS. 13 to 15, the thermoelectric module array 10 includes a first thermoelectric device 1000-1 and a second thermoelectric device 1000-2. The descriptions of FIGS. 1 to 12 may be applied to each of the first thermoelectric device 1000-1 and the second thermoelectric device 1000-2. That is, the first thermoelectric device 1000-1 and the second thermoelectric device 1000-2 each include a fluid flow portion 1100 and a plurality of thermoelectric modules 1200 disposed on the fluid flow portion 1100.

According to the embodiment of the present invention, the first thermoelectric device 1000-1 and the second thermoelectric device 1000-2 may be disposed in the first direction in which the first fluid passes. Accordingly, since a plurality of thermoelectric devices may be disposed in multiple stages on the path through which the first fluid passes, the maximum number of thermoelectric devices can be disposed in a limited space, thereby increasing power generation efficiency.

According to the embodiment of the present invention, the first thermoelectric device 1000-1 includes a plurality of thermoelectric modules 1200-1A and 1200-2A, and the second thermoelectric device 1000-2 includes a plurality of thermoelectric modules 1200-1B and 1200-2B.

Accordingly, the thermoelectric module 1200-1A and the thermoelectric module 1200-1B are disposed adjacent to each other in the first direction, and the thermoelectric module 1200-2A and the thermoelectric module 1200-2B are disposed adjacent to each other in the first direction. In this case, the thermoelectric module 1200-1A and the thermoelectric module 1200-1B may be disposed on the same plane, and the thermoelectric module 1200-2A and the thermoelectric module 1200-2B may be disposed on the same plane.

In this case, the thermoelectric module 1200-1A may include a first-side terminal electrode 1200-1AT that extends toward the first side of the thermoelectric element in the second direction, and a first-side connector 1200-1AC disposed on the first-side terminal electrode 1200-1AT, and the thermoelectric module 1200-2A may include a second-side terminal electrode 1200-2AT that extends toward the second side of the thermoelectric element in the second direction, and a second-side connector 1200-2AC disposed on the second-side terminal electrode 1200-2AT.

Similarly, the thermoelectric module 1200-1B may include a first-side terminal electrode 1200-1BT that extends toward the first side of the thermoelectric element in the second direction, and a first-side connector 1200-1BC disposed on the first-side terminal electrode 1200-1BT, and the thermoelectric module 1200-2B may include a second-side terminal electrode 1200-2BT that extends toward the second side of the thermoelectric element in the second direction, and a second-side connector 1200-2BC disposed on the second-side terminal electrode 1200-2BT. In this specification, the first-side terminal electrodes 1200-1AT and 1200-1BT and the second-side terminal electrode 1200-2AT and 1200-2BT may be referred to as an extension portion of the first electrode disposed on the first substrate of the thermoelectric module, and the description regarding the terminal electrode 400 described above may be applied.

In this case, the first-side connector 1200-1AC of the thermoelectric module 1200-1A and the first-side connector 1200-1BC of the thermoelectric module 1200-1B are sequentially disposed adjacent to each other in the first direction, and the second-side connector 1200-2AC of the thermoelectric module 1200-2A and the second-side connector 1200-2BC of the thermoelectric module 1200-2B are sequentially disposed adjacent to each other in the first direction. As illustrated, the first-side connector 1200-1AC of the thermoelectric module 1200-1A includes a pair of the first-side connectors, and similarly, the first-side connector 1200-1BC of the thermoelectric module 1200-1B, the second-side connector 1200-2AC of the thermoelectric module 1200-2A, and the second-side connector 1200-2BC of the thermoelectric module 1200-2B each include a pair of connectors. As illustrated, the pair of connectors included in one thermoelectric module are disposed adjacent to each other in the first direction through which the high temperature first fluid passes.

Additionally, a heat sink 1220-1A included in the thermoelectric module 1200-1A, a heat sink 1220-2A included in the thermoelectric module 1200-2A, a heat sink 1220-1B included in the thermoelectric module 1200-1B, and a heat sink 1220-2B included in the thermoelectric module 1200-2B each include a groove formed in the first direction so that the first fluid can flow in the first direction. For example, each of the heat sinks is disposed on the second substrate of the thermoelectric device, and may have a shape in which a flat-shaped base material is regularly folded at a predetermined pitch. Thus, the heat sink may include an uneven shape. For example, as illustrated in FIG. 15, the heat sink may have a structure in which a plurality of grooves 1500 and a plurality of protrusions 1510 are alternately disposed in the second direction, and the plurality of grooves 1500 and the plurality of protrusions 1510 each extend in the first direction. That is, it has a structure in which a groove is disposed between two protrusions, and in this specification, the groove may be used interchangeably with a recessed portion. Accordingly, the first fluid may flow in the first direction along the groove 1500 and the protrusion 1510 of the heat sink. Additionally, the first-side connector 1200-1AC and the first-side connector 1200-1BC may be disposed parallel to an extension direction of the protrusion 1510, and both a pair of connectors included in the first-side connector 1200-1AC and a pair of connectors included in the first-side connector 1200-1BC may be disposed parallel to the extension direction of the protrusion 1510. Likewise, the second-side connector 1200-2AC and the second-side connector 1200-2BC may be disposed parallel to the extension direction of the protrusion 1510, and both a pair of connectors included in the second-side connector 1200-2AC and a pair of connectors included in the second-side connector 1200-2BC may be disposed parallel to the extension direction of the protrusion 1510.

In this case, each of the heat sinks may include a plurality of sub-heat sinks. For example, the heat sink 1220-1A may include four sub-heat sinks 1220-11AS, 1220-12AS, 1220-21AS, and 1220-22AS. In this case, a structure of the substrate and electrodes disposed under the four sub-heat sinks may refer to the drawings exemplified in FIGS. 11 and 12, but is not limited thereto. Here, each of the heat sinks is illustrated as being divided into four, but is not limited thereto, and may have a two-part structure, a four-part structure as exemplified in FIGS. 7 to 12, or a six-part structure, an eight-part structure, and the like that are not illustrated.

In this case, the first substrate 1212 which is a lower substrate of the first thermoelectric device 1000-1 may include a region in which the heat sink is disposed and an extension region that extends in a second direction from the region in which the heat sink is disposed. Here, the region in which the heat sink is disposed may mean the first region A1 described above with reference to FIGS. 5 and 6, that is, the effective region in which the first electrode and the second electrode vertically overlap. Here, a distance of the extension region that extends in the second direction from the region in which the heat sink is disposed, that is, the second region A2 described above with reference to FIGS. 5 and 6 may be greater than a shortest distance between the plurality of protrusions 1510 within the heat sink. For example, the distance of the extension region that extends in the second direction from the region in which the heat sink is disposed may be 1.5 times or more and 7.5 times or less the shortest distance between the plurality of protrusions 1510 within the heat sink. Thus, since the number of the plurality of protrusions 1510 accommodated within the heat sink per unit area increases, heat exchange efficiency per unit area can be increased, an insulation distance can be secured, and the withstand voltage performance can be improved.

In this case, a distance d1 in the first direction between the heat sink 1220-1A of the thermoelectric module 1200-1A and the heat sink 1220-1B of the thermoelectric module 1200-1B may be smaller than a horizontal distance D2 in the second direction between the heat sink 1220-1A of the thermoelectric module 1200-1A and the edge of the first substrate 1212 of the thermoelectric module 1200-1A in the second direction. Here, the horizontal distance D2 in the second direction between the heat sink 1220-1A of the thermoelectric module 1200-1A and the edge of the first substrate 1212 of the thermoelectric module 1200-1A in the second direction may be referred to as a distance of the extension region that extends in the second direction from the region in which the heat sink is disposed. For example, the horizontal distance D2 in the second direction between the heat sink of the thermoelectric module 1200-1A and the edge of the first substrate 1212 of the thermoelectric module 1200-1A in the second direction may be 1.1 times or more and 2.5 times or less, preferably 1.5 times or more and 2.5 times or less, and more preferably 2 times or more and 2.5 times or less the distance D1 in the first direction between the heat sink of the thermoelectric module 1200-1A and the heat sink of the thermoelectric module 1200-1B. Accordingly, since an area of the heat sink accommodated per unit area can be increased, the heat exchange efficiency per unit area can be maximized, and an insulation distance and withstand voltage characteristics can be simultaneously secured.

As illustrated in FIGS. 13 to 15, when the heat sink of each of the thermoelectric modules includes a plurality of split heat sinks, for example, a four-part heat sink, the distance D1 in the first direction between the heat sink of the thermoelectric module 1200-1A and the heat sink of the thermoelectric module 1200-1B may be greater than or equal to a distance D3 in the first direction between the plurality of sub-heat sinks of the thermoelectric module 1200-1A. For example, the distance D1 in the first direction between the heat sink of the thermoelectric module 1200-1A and the heat sink of the thermoelectric module 1200-1B may be 1 times or more and 2 times or less, and preferably 1 times or more and 1.6 times or less the distance D3 in the first direction between the plurality of sub-heat sinks of the thermoelectric module 1200-1A. When a ratio between the distance D1 in the first direction between the heat sink of the thermoelectric module 1200-1A and the heat sink of the thermoelectric module 1200-1B and the distance D3 in the first direction between the plurality of sub-heat sinks of the thermoelectric module 1200-1A deviates from the above numerical range, space efficiency and sealing workability may be reduced.

According to the embodiment of the present invention, the heat sink and the connector are disposed to overlap in the second direction perpendicular to the first direction in which the first fluid passes, the connectors within the plurality of thermoelectric modules disposed sequentially in the first direction are disposed sequentially in the first direction, and a pair of connectors within one thermoelectric module are also disposed sequentially in the first direction. Accordingly, since the connector is not disposed on the path of the first fluid passing through the heat sink, a problem of heat of the first fluid being lost in the region in which the connector is disposed before passing through the heat sink and a problem of the connector being damaged due to the heat of the first fluid can be prevented. In particular, when the connector is disposed in a space between the plurality of thermoelectric modules that are sequentially disposed in the first direction which is the direction in which the first fluid flows, the path of the first fluid becomes longer as a result, and thus the number of thermoelectric modules that can be accommodated within the limited path of the first fluid may be limited, and when the connector is disposed according to the embodiment of the present invention, the number of thermoelectric modules that can be accommodated within the path of the first fluid can be maximized. In addition, when the connector is disposed according to the embodiment of the present invention, the path of the first fluid can be shortened, and thus a pressure difference between before and after the first fluid passes through the thermoelectric module array 10 can be reduced, thereby improving the power generation performance.

In addition, when the connector is disposed in the space between the plurality of thermoelectric modules that are sequentially disposed in the first direction which is the direction in which the first fluid flows, a distance between the plurality of thermoelectric modules is increased by the space occupied by the connector in the first direction, and an eddy current of the first fluid may occur within this space. Such an eddy current may cause a problem of a differential pressure that is a pressure difference between before and after the first fluid passes through the thermoelectric module array 10 increasing.

On the other hand, according to the embodiment of the present invention, since a length of the first substrate can be shortened on the path through which the first fluid passes in the first direction, a ratio of the length of the heat sink to the length of the first substrate can become closer to 1. Accordingly, the differential pressure which is the pressure difference between before and after the first fluid passes through the heat sink can be reduced.

Although not illustrated, the terminal electrodes 1200-1AT, 1200-2AT, 1200-1BT, and 1200-2BT of the thermoelectric modules are disposed on the first substrate of the thermoelectric element, are disposed on the side surfaces of the plurality of first electrodes, and can be electrically connected to the thermoelectric element.

According to the embodiment of the present invention, the first-side connector 1200-1AC of the thermoelectric module 1200-1A and the first-side connector 1200-1BC of the thermoelectric module 1200-1B may be connected to each other in the first direction by a wire W. Similarly, the first-side connector 1200-2AC of the thermoelectric module 1200-2A and the first-side connector 1200-2BC of the thermoelectric module 1200-2B may be connected to each other in the first direction by the wire W. Accordingly, the plurality of thermoelectric devices may be connected to each other without extending the path of the first fluid or disturbing the flow of the first fluid, and since the high temperature first fluid does not pass over the wire W, damage to the wire W can be prevented.

In this case, the first-side connector 1200-1AC of the thermoelectric module 1200-1A and the first-side connector 1200-1BC of the thermoelectric module 1200-1B may be covered together by one shield member 1300. Similarly, the second-side connector 1200-2AC of the thermoelectric module 1200-2A and the second-side connector 1200-2BC of the thermoelectric module 1200-2B may be covered together by one shield member 1300. That is, one shield member 1300 may extend in the first direction to cover the plurality of connectors together. In this case, the shield member 1300 may include a thermal insulating material. Thus, the connector located under the shield member 1300 can be protected from the heat of the first fluid. Alternatively, the shield member 1300 may include an electrical insulating material. Thus, the connector disposed under the shield member 1300 can be protected from electrical damage. Alternatively, the shield member 1300 may include both a thermal insulating material and an electrical insulating material.

In FIGS. 13 to 15, an example of arranging the first thermoelectric device 1000-1 and the second thermoelectric device 1000-2 are described, but the number and arrangement of the thermoelectric devices can be increasingly varied. For example, two or more thermoelectric devices may be disposed in the second direction, or two or more thermoelectric devices may be disposed in the third direction.

According to the embodiment of the present invention, since the number of thermoelectric devices may be increased or decreased according to a length of the path through which the first fluid passes or a size of the space through which the first fluid passes, maximum power generation efficiency per unit volume and unit heat amount can be obtained.

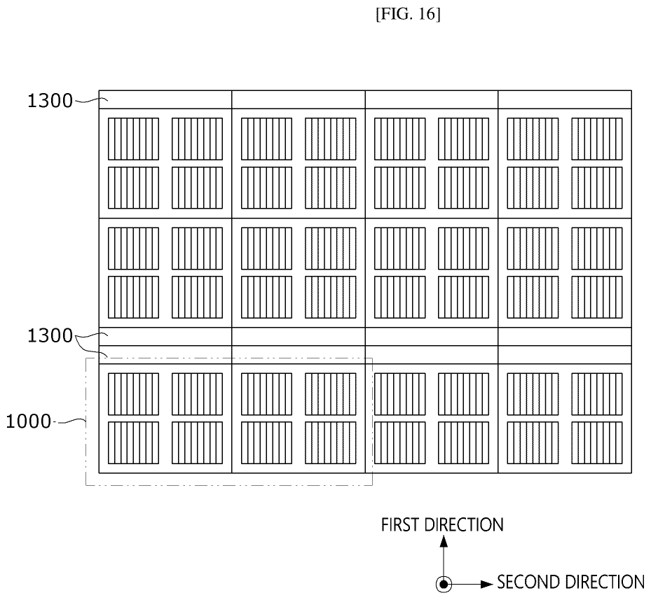

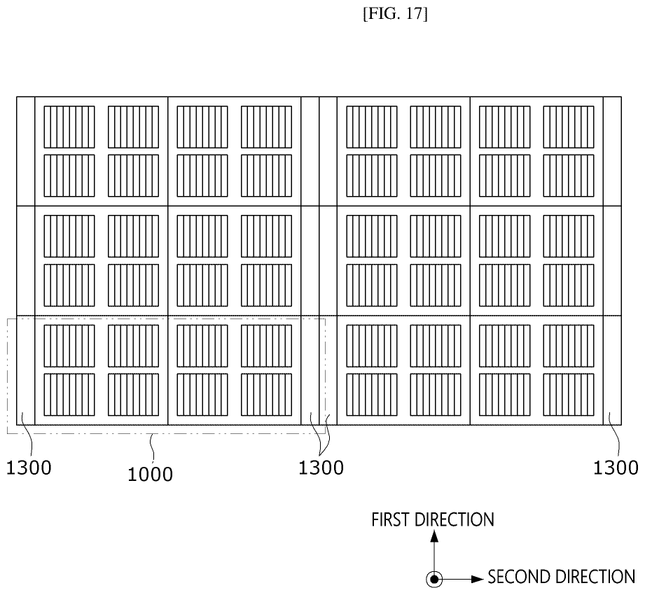

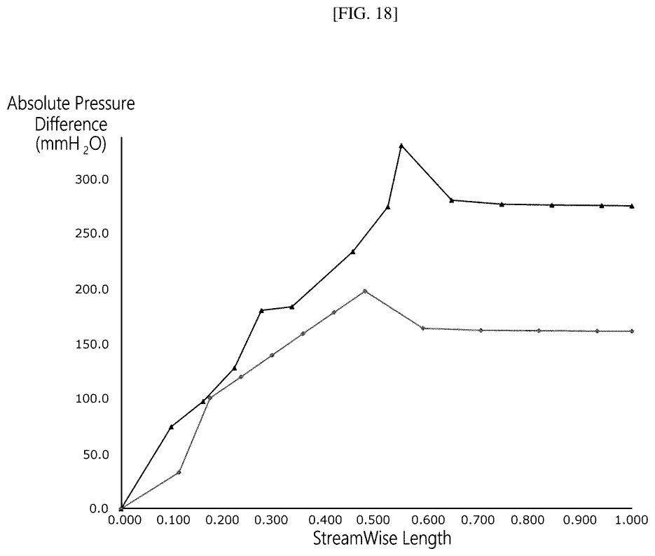

FIG. 16 is a layout diagram of a thermoelectric system according to a comparative example, FIG. 17 is a layout diagram of a thermoelectric system according to an embodiment, and FIG. 18 is a diagram showing a simulation of the differential pressure according to the length of the path through which the first fluid passes in the comparative example and the embodiment.

Referring to FIGS. 16 and 17, the thermoelectric system according to the comparative example and the thermoelectric system according to the embodiment each include a total of six thermoelectric devices, two of which are disposed in the second direction and three of which are disposed in the first direction.

Referring to FIG. 16, in the thermoelectric system according to the comparative example, a connector (not illustrated) and a shield member 1300 are disposed in the second direction between thermoelectric devices disposed in the first direction, and referring to FIG. 17, in the thermoelectric system according to the embodiment, a connector (not illustrated) and a shield member 1300 are disposed in the first direction on a side portion of the thermoelectric device in the second direction.

Referring to FIG. 18, a black line represents results according to the comparative example, and a red line represents results according to the embodiment. Accordingly, it can be understood that the arrangement of the thermoelectric system according to the embodiment has a lower differential pressure than the arrangement of the thermoelectric system according to the comparative example when the path through which the first fluid passes is the same. Here, the differential pressure refers to the pressure difference between before and after the first fluid passes through the thermoelectric system, and as the differential pressure becomes larger, the power generation performance is lowered.

That is, referring to FIG. 18, it can be understood that the arrangement of the thermoelectric system according to the embodiment can obtain higher power generation performance than the arrangement of the thermoelectric system according to the comparative example.

When the thermoelectric element or thermoelectric module according to the embodiment of the present invention is used in a transportation device such as a ship or automobile, power generation can be achieved utilizing waste heat discharged from the exhaust side of an engine, and the generated energy can be stored in batteries of the transportation device and supplied to various devices within the transportation device, such as lighting and gas circulation devices. When the thermoelectric element according to the embodiment of the present invention is disposed on the intake side of an engine, the thermoelectric element according to the embodiment of the present invention can be used not only as a power generation device but also as a temperature control device. When the thermoelectric element according to the embodiment of the present invention is used as a temperature control device, fuel efficiency of an engine can be improved by lowering a temperature of a gas injected into the engine and thus increasing an amount of the gas injected into the engine. Accordingly, the engine in the transportation device and the thermoelectric element according to the embodiment of the present invention may influence each other and have functional integration or technical interoperability. In addition, in the shipping and transportation industries using a transportation device to which the thermoelectric element according to the embodiment of the present invention is applied, transportation costs can be reduced and an eco-friendly industrial environment can be created due to the thermoelectric element according to the embodiment of the present invention, and it is possible to achieve functional integration or technical interoperability with the thermoelectric device according to the embodiment of the present invention.

When the thermoelectric element according to the embodiment of the present invention is used in a power plant, the efficiency of fuel used compared to energy produced can be controlled using heat generated in the power plant, and thus by adjusting the energy production cost and the eco-friendly industrial environment, the thermoelectric element according to the embodiment of the present invention and the power plant can achieve functional integration or technical interoperability.

When the thermoelectric element according to the embodiment of the present invention is used in a plant such as a steel mill, energy consumption in the plant can be reduced by producing energy through power generation using waste heat generated in the plant, and when the thermoelectric element is used as a temperature control device, it influences other components of the plant by controlling a temperature in a manufacturing stage of a product or within the plant, and thus the thermoelectric element according to the embodiment of the present invention and other components of the plant can achieve functional integration or technical interoperability.

The thermoelectric element according to the embodiment of the present invention can be used as a low-power supply device for supplying energy to a temperature sensor or sensor in a wireless network. That is, since it is possible to achieve a permanent energy supply to sensors, and the like, when the thermoelectric element is used as a temperature sensor installed underground or as a power supply device for a temperature sensor, it is possible to achieve functional integration or technical interoperability with a wireless network system.

The thermoelectric element according to the embodiment of the present invention can be used as a temperature control device, and when the thermoelectric element is used in an electric vehicle, a battery charging device, and the like, functional integration or technical interoperability can be achieved through functions such as increasing stability of the electric vehicle or battery charging device by controlling a temperature of the electric vehicle or battery charging device.

Although the present invention has been described above with reference to preferred embodiments thereof, it will be understood by those skilled in the art that various modifications and changes may be made to the present invention without departing from the gist and scope of the present invention as set forth in the claims below.

1. A thermoelectric module array comprising:
a first thermoelectric module; and
a second thermoelectric module disposed adjacent to the first thermoelectric module in a first direction,
wherein each of the first thermoelectric module and the second thermoelectric module includes a heat sink and a connector,
the heat sink includes a groove formed to extend in the first direction so that a first fluid flows in the first direction, and
a first connector of the first thermoelectric module and a second connector of the second thermoelectric module are disposed adjacently in the first direction.

2. The thermoelectric module array of claim 1, wherein the first connector of the first thermoelectric module and the second connector of the second thermoelectric module are connected by a wire that extends in the first direction.

3. The thermoelectric module array of claim 1, wherein the heat sink and the connector are disposed to overlap each other in a second direction perpendicular to the first direction.

4. The thermoelectric module array of claim 1, further comprising a shield member configured to cover the first connector and the second connector together and disposed to extend in the first direction.

5. The thermoelectric module array of claim 1, wherein each of a first heat sink of the first thermoelectric module and a second heat sink of the second thermoelectric module includes a plurality of sub-heat sinks, and
a distance between the first heat sink of the first thermoelectric module and the second heat sink of the second thermoelectric module is greater than or equal to a distance between the plurality of sub-heat sinks within the first heat sink.

6. The thermoelectric module array of claim 1, wherein each of the first thermoelectric module and the second thermoelectric module includes a first substrate on which the connector is disposed and a second substrate on which the heat sink is disposed, and
a plurality of P-type legs and a plurality of N-type legs are disposed between the first substrate and the second substrate.

7. The thermoelectric module array of claim 6, further comprising a first electrode disposed between the plurality of P-type legs and the plurality of N-type legs and the first substrate,
wherein the first electrode includes an extension portion which extends in a second direction perpendicular to the first direction, and
the connector is disposed on the extension portion.

8. The thermoelectric module array of claim 1, wherein the first thermoelectric module and the second thermoelectric module are disposed on the same plane.

9. The thermoelectric module array of claim 6, wherein a distance in the first direction between the first heat sink of the first thermoelectric module and the second heat sink of the second thermoelectric module is smaller than a distance between the first heat sink of the first thermoelectric module and an edge of the first substrate of the first thermoelectric module in the second direction perpendicular to the first direction.

10. The thermoelectric module array of claim 1, wherein the first thermoelectric module and the second thermoelectric module include a fluid flow portion disposed on a surface opposite to a surface on which the heat sink is disposed and having a passage through which a second fluid flows.

11. The thermoelectric module array of claim 5, wherein the distance between the first heat sink of the first thermoelectric module and the second heat sink of the second thermoelectric module is one time or more and two times or less the distance between the plurality of sub-heat sinks within the first heat sink.

12. The thermoelectric module array of claim 7, wherein:
the first substrate includes a region in which the heat sink is disposed and an extension region which extends in the second direction from the region in which the heat sink is disposed,
the heat sink includes an uneven shape, and
a distance of the extension region extended in the second direction is greater than a distance between protrusions having the uneven shape.

13. The thermoelectric module array of claim 12, wherein the distance of the extension region extended in the second direction is 1.5 times or more and 7.5 times or less the distance between the protrusions.

14. A thermoelectric module array comprising:
a first thermoelectric device; and
a second thermoelectric device disposed adjacent to the first thermoelectric device in a first direction,
wherein the first thermoelectric device includes a plurality of thermoelectric modules disposed in a second direction perpendicular to the first direction,
wherein the second thermoelectric device includes a plurality of thermoelectric modules disposed in the second direction,
wherein each of the plurality of thermoelectric modules included in the first thermoelectric device and the plurality of thermoelectric modules included in the second thermoelectric device includes a heat sink and a connector,
wherein the heat sink includes a groove formed to extend in the first direction so that a first fluid flows in the first direction,
wherein a connector of a thermoelectric module disposed on a first side in the second direction among the plurality of thermoelectric modules included in the first thermoelectric device and a connector of a thermoelectric module disposed on the first side in the second direction among the plurality of thermoelectric modules included in the second thermoelectric device are disposed adjacently in the first direction, and
wherein a connector of a thermoelectric module disposed on a second side in the second direction among the plurality of thermoelectric modules included in the first thermoelectric device and a connector of a thermoelectric module disposed on the second side in the second direction among the plurality of thermoelectric modules included in the second thermoelectric device are disposed adjacently in the first direction.

15. The thermoelectric module array of claim 14, wherein a connector is not disposed between the plurality of thermoelectric modules included in the first thermoelectric device and between the plurality of thermoelectric modules included in the second thermoelectric device.
